(19) United States
(12) Patent Application Publication
(10) Pub. No.: US 2005/0030056 A1
(43) Pub. Date: Feb. 10, 2005

(54) Apparatus for measuring VS parameters in a wafer burn-in system

(75) Inventors: Sang-kyung Woo, Seoul (KR); Tae-eul Jeon, Gyunggi-do (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: From Thirty Incorporated, Gyuggi-do (KR)

(21) Appl. No.: 10/875,145

(22) Filed: Jun. 23, 2004

(30) Foreign Application Priority Data
Jun. 25, 2003 (KR) 10-2003-0041499

(51) Int. Cl. G01R 31/26

(52) U.S. Cl. 324/765

(57) ABSTRACT

The present invention relates to an apparatus for measuring voltage parameters in a wafer burn-in system which can simultaneously measure VS parameters for a great plenty of DUTs through a single test process. According to the present invention, there is provided an apparatus for measuring VS parameters in a wafer burn-in system, comprising: an FPGA for generating control signals including a driving voltage for measuring the VS parameters; a D/A converter for converting the digital control signals provided from the FPGA to analog control signals and then outputting the analog control signals; a VS circuit provided with n same circuit blocks, which are connected one-to-one to n DUTs (Devices Under Test), photo MOSs being provided at output stages of each of the n circuit blocks, wherein the control signals provided from the D/A converter are selectively transmitted to the respective DUTs by selectively switching on/off the photo MOSs in the respective circuit blocks. According to the present invention, by improving the degree of integration of the VS board, which is provided for measuring the VS parameters in the wafer burn-in system, the number of the VS parameters, which can be measured through the single test process, increases, and therefore, the time required in the wafer burn-in test process can be reduced. Furthermore, a noise voltage inputted from adjacent DUTs can be effectively removed.

### BACKGROUND OF THE INVENTION

1. Field of Invention

The present invention relates to a wafer burn-in system, and more particularly, to an apparatus which is mounted in a wafer burn-in system to measure VS (Voltage Supply) parameters for respective semiconductor devices on a wafer.

2. Description of the Prior Art

Generally, a wafer burn-in process is a kind of test process for determining whether semiconductor devices on a wafer are normal or abnormal by applying a higher voltage than conventional working voltage (5.0V) to the semiconductor devices at a high temperature (about 125° C.) that is a worse condition than a working condition of the semiconductor devices, before the semiconductor devices are supplied to final customers. The wafer burn-in process is generally performed in a post-process of a semiconductor manufacturing process. In addition, by performing such a wafer burn-in process, reliability and productivity of the semiconductor devices can be secured at an early stage.

In connection with this, FIG. 1 shows the general configuration of a conventional wafer burn-in system. The conventional wafer burn-in system comprises a computer 100, a wafer loading apparatus 200, a performance measuring board 250, and a main testing apparatus 300, each of which is generally constituted as an independent separate apparatus. That is, the wafer loading apparatus 200, the performance measuring board 250, and the main testing apparatus 300 shown in FIG. 1, each of which is constituted as an independent separate apparatus, are interconnected by predetermined connecting manners, and then, perform the wafer burn-in process.

Referring to FIG. 1, the functions of these components will be described. First, the computer 100 comprising a general personal computer or workstation controls the wafer burn-in process by providing execution conditions and commands for the wafer burn-in process, which are inputted by a user, to the main testing apparatus 300, which will be described below, and monitors progressive states of the process according thereto.

The wafer loading apparatus 200 functions to deliver the wafer to be tested to the performance measuring board 250, which will be described below, load and align the wafer, and unload the wafer after the test is completed.

The performance measuring board 250, which tests the wafer that is loaded by the wafer loading apparatus 200, comprises a plurality of measuring devices for performing the burn-in test, a plurality of pins for connecting to the wafer, a display (e.g., LED) for displaying the progressive states of the test, and the like. The performance measuring board 250 transfers various test signals including predetermined voltages according to the burn-in process on the basis of control signals provided from the main testing apparatus 300, which will be described below, to the wafer through a plurality of the pins. In addition, the performance measuring board 250 also transmits signals outputted from the wafer correspondingly to the test signals to the main testing apparatus 300.

The main testing apparatus 300 performs and controls the whole test process according to the wafer burn-in process on the basis of the execution commands inputted through the aforementioned computer 100. Connected to the aforementioned performance measuring board 250, the main testing apparatus 300 generates the various test signals including the predetermined voltage for performing the test, and then, provides them to the performance measuring board 250. In addition, combining output signals provided from performance measuring board 250 again, the main testing apparatus 300 provides test result signals according to the combined output signals to a separate alarm device or transmits them to its own monitor (not shown) or the computer 100.

Therefore, the main testing apparatus 300 comprises various components for performing the wafer burn-in test, such as, for example, timing clock generating means, test wave generating means, memory means for storing control commands for the execution, wave monitoring means, drivers, VS parameter measuring means, voltage converting means, and the like. In addition, such components are mounted in the main testing apparatus 300 in the form of a plurality of boards. Further, the main testing apparatus 300 is also mounted with a CPU for analyzing detecting signals and operations of such components and a display means (e.g., a monitor) for displaying the whole processing states. Particularly, the main testing apparatus 300 is mounted with a plurality of VS (Voltage Supply) boards for supplying predetermined test voltages (programmed voltages) through the performance measuring board 250 to the respective semiconductor devices on the wafer. Here, the respective VS boards generally provide the voltages from −3V to +15V to the performance measuring board 250.

In the meantime, the conventional wafer burn-in system is generally constituted so that the wafer burn-in system operates two (2) stations, each of which comprises the performance measuring board 250 and the wafer loading apparatus 200. Since two VS boards are usually mounted for each station, the wafer burn-in system is mounted with the four (4) VS boards. Furthermore, since each of the VS boards comprises thirty-two (32) same circuit blocks, one of the VS boards can measure thirty-two parameters. That is, each of the VS boards can measure VS parameters for thirty-two DUTs (Devices Under Test) through thirty-two VS circuit blocks constituted by the same circuits. Therefore, the conventional wafer burn-in system constituted by the two stations can measure the VS parameters for 128 DUTs.

FIG. 2 is a view showing the constitution of the VS board mounted in the conventional wafer burn-in system. The conventional VS board comprises an FPGA (Field Programmable Gate Array) 10, a D/A converter 20, a buffer 30, and VS blocks 40-1 to 40-32. As shown in the figure, the conventional VS board comprises the thirty-two VS blocks 40-1 to 40-32 which are constituted by the same circuits and then measures the VS parameters for thirty two DUTs DUT1 to DUT32.

Referring to FIG. 2, each component will be described. First, the FPGA 10 generates and outputs various control signals for driving the VS board, such as, for example, address signals for selecting the respective DUTs, data signals for measuring the VS parameters, enable signals for driving the D/A converter 20, and the like. The D/A converter 20 converts the various control signals, which are provided from the FPGA 10 in digital form, to analog signals, and then, transmits the analog signals through the buffer 30 to the VS blocks 40-1 to 40-32.

In the meantime, each of the VS blocks 40-1 to 40-32 in the VS board is provided with relay switches Ry1, Ry2, and Ry3, as shown in FIG. 2, wherein (Guarding, Sensing, and Forcing) signals for measuring the VS parameters of the DUTs connected to the VS blocks 40-1 to 40-32, respectively, are selectively outputted by selectively controlling an on/off operation of the relay switches Ry1, Ry2, and Ry3 in the VS blocks 40-1 to 40-32. Therefore, the signals outputted from the respective VS blocks 40-1 to 40-32 are transmitted through the performance measuring board (as shown in FIG. 1) to the semiconductor devices on the wafer, so that the VS parameters can be measured.

As a result, when the VS parameters are measured by using the conventional wafer burn-in system which is constituted by the two stations each of which is mounted with two VS boards as described above, the VS parameters for the maximum 128 DUTs can be measured through a measuring process.

However, since a practical wafer is formed with even more semiconductor devices than 128, considerable time is needed to measure the VS parameters for all semiconductor devices formed on the wafer. Particularly, since a diameter of a wafer has a tendency to increase lately, the number of the semiconductor devices formed on the wafer also increases. Therefore, measuring time of the VS parameters for a wafer also increases, so that a novel wafer burn-in system has been required to measure the VS parameters for a great plenty of DUTs through a single process.

If additional VS blocks 40-1 to 40-32 are simply added to the conventional VS board shown in FIG. 2 in order to satisfy the requirement, an increase of the relay switches causes degree of integration of the VS board itself to deteriorate, so that size of the system disadvantageously increases. In addition, since the additional relay switches are expensive, production cost of the VS board also disadvantageously increases

### SUMMARY OF THE INVENTION

Accordingly, the present invention is conceived to solve the aforementioned problems in the prior art. An object of the present invention is to provide an apparatus for measuring voltage parameters in a wafer burn-in system which can simultaneously measure VS parameters for a great plenty of DUTs through a single test while minimizing cost raise.

According to the present invention for achieving the object, there is provided an apparatus for measuring VS parameters in a wafer burn-in system, comprising: an FPGA for generating control signals including a driving voltage for measuring the VS parameters; a D/A converter for converting the digital control signals provided from the FPGA to analog control signals and then outputting the analog control signals; a VS circuit provided with n same circuit blocks, which are connected one-to-one to n DUTs (Devices Under Test), photo MOSs being provided at output stages of each of the n circuit blocks, wherein the control signals provided from the D/A converter are selectively transmitted to the respective DUTs by selectively switching on/off the photo MOSs in the respective circuit blocks.

### BRIEF DESCRIPTION OF THE DRAWINGS

The above and other objects, features and advantages of the present invention will become apparent from the following description of preferred embodiments given in conjunction with the accompanying drawings, in which:

FIG. 1 is a view showing the whole constitution of a conventional wafer burn-in system;

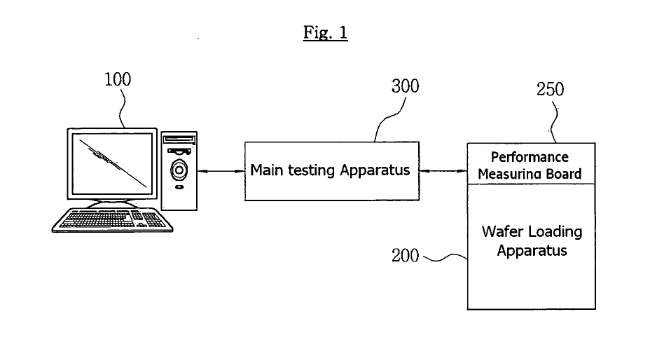

FIG. 2 is a view showing the constitution of a VS board mounted in the conventional wafer burn-in system;

FIG. 3 is a view showing the constitution of a VS board according to an embodiment of the present invention;

FIG. 4 is a graph showing a noise signal measured from an adjacent DUT when using the VS board shown in FIG. 3; and

FIG. 5 is a view showing the constitution of a VS board according to another embodiment of the present invention.

### DETAILED DESCRIPTION OF THE PREFERRED EMBODIMENTS

Hereinafter, preferred embodiments of the present invention will be described in detail with reference to the accompanying drawings.

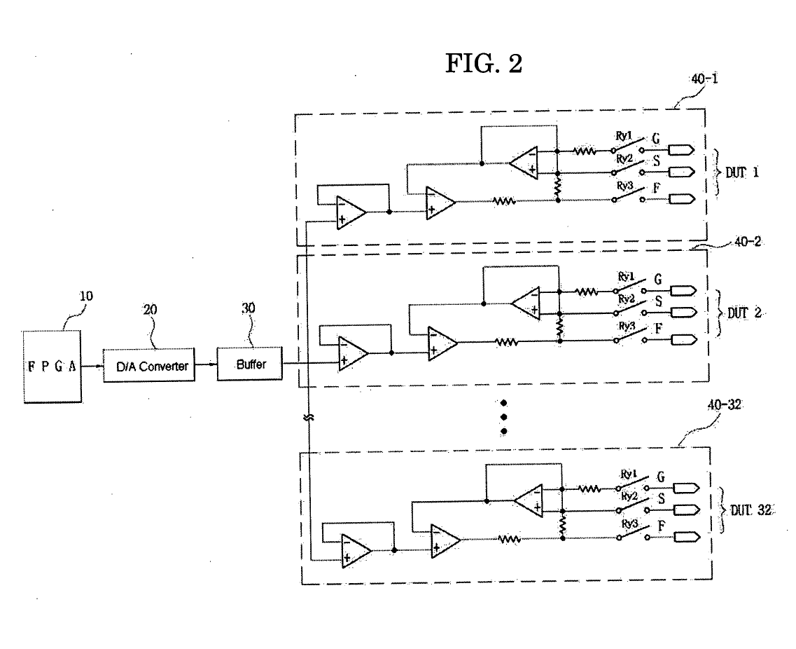

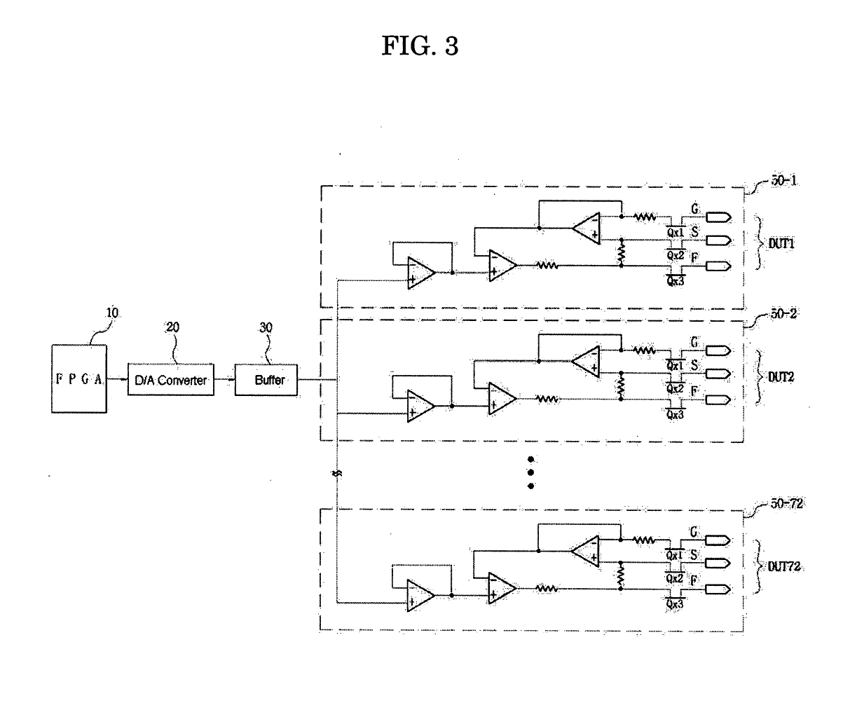

FIG. 3 is a view showing the configuration of an apparatus for measuring voltage parameters, i.e. a VS board, of a wafer burn-in system according to an embodiment of the present invention. The apparatus of the present invention comprises an FPGA 10, a D/A converter 20, a buffer 30, and VS blocks 50-1 to 50-72. First, the FPGA 10, the D/A converter 20, and the buffer 30 shown in FIG. 3 are designated by the same reference numerals as those of the corresponding components shown in FIG. 2 since they have the same functions as each other. However, the FPGA of the present invention shown in FIG. 3 should generate larger numbers of address and data signals than the FPGA shown in FIG. 2 since the number of the VS blocks 50-1 to 50-72 is increased as compared with the conventional VS blocks shown in FIG. 2.

Referring to FIG. 3, the VS board according to the present invention is provided with seventy-two (72) VS blocks 50-1 to 50-72, so that the VS board may measure VS parameters for seventy-two DUTs. Therefore, the wafer burn-in system, which operates two stations each of which is mounted with two such VS boards, can measure the parameters for 288 DUTs through a single test process. Particularly, in the VS board of the present invention shown in FIG. 3, photo MOSs (Metal-Oxide Semiconductors) Qx1, Qx2 and Qx3 as switches are provided at output stages of each of the VS blocks 50-1 to 50-72. Here, although the photo MOS has the same constitution of the photo coupler, the photo MOS is a switching element constituted by a MOS-FET capable of receiving a high voltage and a high current at the output stage.

As a result, while the conventional VS board can measure the VS parameters by selecting the respective DUTs by means of an on/off control of the relay switches which are provided in each VS block, the VS board of the present invention causes the respective DUTs to be selectively switched by using the photo MOSs Qx1, Qx2 and Qx3, which are inexpensive and easy to control, instead of the relay switches. In addition, by providing seventy-two VS blocks each of which is mounted with such photo MOSs, the VS board can simultaneously measure the VS parameters for the seventy-two DUTs.

In the meantime, a photo MOS generally has a very high capacitance compared with a relay switch. Table 1 shows comparison results of an internal resistance and an internal capacitance of the relay switch used in the conventional VS board shown in FIG. 2 and the photo MOS of the present invention shown in FIG. 3

TABLE 1

| | | Relay Switch | | Photo MOS | |
|---|---|---|---|---|---|
| Resistance | ON | 150 | mΩ | 125 | mΩ |
| | OFF | 10¹⁰ | Ω | 10¹⁰ | Ω |
| Capacitance | ON | 0.2 | pF | 0.8 | pF |
| | OFF | 1.5 | pF | 265 | pF |

As shown in Table 1, it is noted that when the corresponding VS block is turned off, the internal capacitance of the photo MOS of the present invention shown in FIG. 3 is very higher than that of the relay switch used in the conventional VS board. Such a phenomenon may affect the adjacent VS blocks while any one of the VS blocks is driven. That is, in the process for measuring the VS parameter for any one of the DUTs, the adjacent DUTs that are not measured are affected, which may cause the semiconductor devices to be damaged.

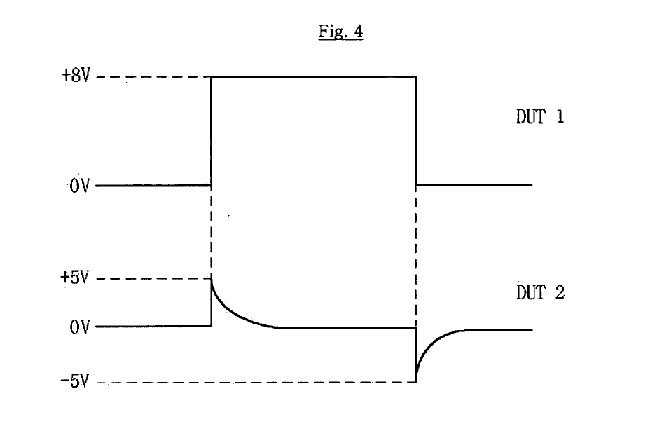

FIG. 4 is a graph showing a measured noise signal inputted in the DUT DUT2, which is not tested, in the process for measuring the VS parameter for the DUT DUT1 using the VS board shown in FIG. 3. As shown in FIG. 4, when a voltage of +8V is applied to the DUT DUT1, a voltage of about ±5V is transmitted to the DUT DUT2. Accordingly, since such a noise signal (voltage) is transmitted to the adjacent DUTs for which the burn-in test is not performed, whereby the corresponding semiconductor device may be damaged. To prevent that, therefore, it is necessary to remove the noise signals introduced into the adjacent DUTs when a VS parameter is measured by driving any one of the DUTs.

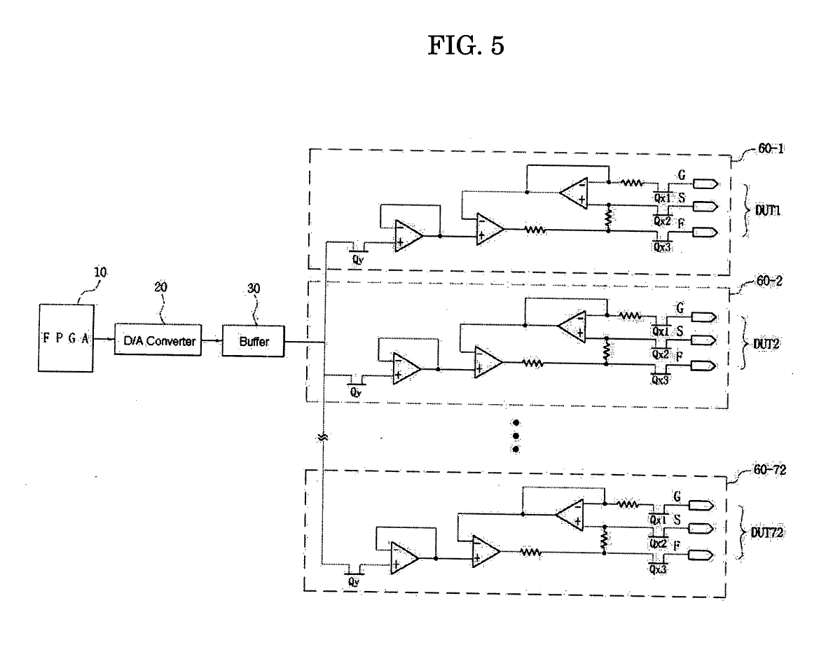

FIG. 5 is a view showing the constitution of a VS board according to another embodiment of the present invention taking the foregoing into consideration. Compared with the previous embodiment shown in FIG. 3, in the present embodiment shown in FIG. 5, an additional photo MOS Qy as a circuit element for removing a noise signal is further provided at an input stage of each of the VS blocks 60-1 to 60-72. At this time, the photo MOS Qy provided at the input stage of each of the VS blocks 60-1 to 60-72 functions to attenuate the noise voltage inputted from the adjacent VS block, in which the VS parameter is measured when the corresponding VS blocks are not driven.

For example, in the VS board shown in FIG. 5, when control signals including a driving voltage from the FPGA 10 are applied to the first VS block 60-1 in order to measure the VS parameter for the DUT DUT1, the control signals including the driving voltage outputted through the buffer 30 are transmitted to the first VS block 60-1. Then, the control signals are transmitted to the DUT DUT1 connected to the output stages of the first VS block 60-1, so that the VS parameter for the DUT DUT1 is measured.

In the meantime, although the control signals including the driving voltage are not practically applied to the second VS block 60-2 adjacent to the first VS block 60-1, the noise voltage generated from the driving voltage applied to the first VS block 60-1 is introduced into the second VS block 60-2. At this time, the noise voltage introduced into the second VS block 60-2 is transmitted to the photo MOS Qy provided at the input stage, and then, is mostly attenuated by means of the photo MOS Qy.

As a result of the test, which is performed by applying the driving voltage of +8V to the first VS block 60-1 using the VS board of the embodiment shown in FIG. 5, the noise voltage outputted from the second VS block 60-2 and transmitted to the DUT DUT2 is about +0.1V, which does not affect the semiconductor device.

In result, since the present invention improves degree of integration of the VS board by using the photo MOSs instead of the relay switches at the output stages of each VS block, the 288 VS parameters can be simultaneously measured in the wafer burn-in system.

According to the aforementioned present invention, by improving the degree of integration of the VS board, which is provided for measuring the VS parameters in the wafer burn-in system, the number of the DUTs which can measure VS parameters through the single test process increases, and therefore, the time required in the wafer burn-in test process can be reduced. Furthermore, the photo MOSs used at the input stages of the VS board can effectively remove the noise voltage.

The aforementioned embodiments and the drawings only intend to explain the present invention, and do not intend to limit the scope of the present invention. Also, the present invention is not limited thereto but should be defined by the appended claims and their equivalents, since it will be apparent to those skilled in the art that various substitutions, modifications and changes may be made thereto without departing from the scope and spirit of the invention.

1. An apparatus for measuring VS parameters of semiconductor devices formed on a wafer in a wafer burn-in system, comprising:
an FPGA for generating control signals including a driving voltage for measuring the VS parameters;
a D/A converter for converting the digital control signals provided from the FPGA to analog control signals and then outputting the analog control signals;
a VS circuit provided with n same circuit blocks, which are connected one-to-one to n DUTs (Devices Under Test), photo MOSs being provided at output stages of each of the n circuit blocks, wherein the control signals provided from the D/A converter are selectively transmitted to the respective DUTs by selectively switching on/off the photo MOSs in the respective circuit blocks.

2. The apparatus as claimed in claim 1, wherein the VS circuit is provided with seventy-two (72) circuit blocks, being connected to the seventy-two (72) DUTs, respectively.

3. The apparatus as claimed in claim 1, wherein an input stage of each of the circuit blocks is provided with a circuit element for attenuating a noise voltage.

4. The apparatus as claimed in claim 3, wherein the circuit element for attenuating the noise voltage comprises a photo MOS.
